(19) United States
(12) Patent Application Publication
(10) Pub. No.: US 2023/0220544 A1
(43) Pub. Date: Jul. 13, 2023

(54) IN-FEATURE WET ETCH RATE RATIO REDUCTION

(71) Applicant: Lam Research Corporation, Fremont, CA (US)

(72) Inventors: Awnish Gupta, Hillsboro, OR (US); Ian John Curtin, Portland, OR (US); Douglas Walter Agnew, Portland, OR (US); Frank Loren Pasquale, Tigard, OR (US); Eli Jeon, Sherwood, OR (US); Adrien LaVoie, Newberg, OR (US)

(21) Appl. No.: 18/000,562

(22) PCT Filed: Jun. 1, 2021
(86) PCT No.: PCT/US2021/035269

§ 371 Date: Dec. 2, 2022

Related U.S. Application Data
(60) Provisional application No. 62/704,918, filed on Jun. 3, 2020.

(51) Int. Cl. C23C 16/40; C23C 16/455

(52) U.S. Cl. CPC C23C 16/401; C23C 16/45527; C23C 16/45557; C23C 16/45553

(57) ABSTRACT

Various embodiments herein relate to methods and apparatus for depositing silicon oxide using thermal ALD or thermal CVD. In one aspect of the disclosed embodiments, a method for depositing silicon oxide is provided, the method including: (a) receiving the substrate in a reaction chamber; (b) introducing a first flow of a first reactant into the reaction chamber and exposing the substrate to the first reactant, where the first reactant includes a silicon-containing reactant; (c) introducing a second flow of a second reactant into the reaction chamber to cause a reaction between the first reactant and the second reactant, (i) where the second reactant includes hydrogen (H2) and an oxygen-containing reactant, (ii) where the reaction deposits silicon oxide on the substrate, and (iii) where the reaction is initiated when a pressure in the reaction chamber is greater than 10 Torr and equal to or less than about 40 Torr.

### RELATED APPLICATIONS

A PCT request form is filed concurrently with this specification as part of the present application. Each application that the present application claims benefit of or priority to as identified in the concurrently filed PCT request form is incorporated by reference herein in its entirety and for all purposes.

### BACKGROUND

Many semiconductor device fabrication processes involve formation of films including silicon-containing films such as silicon oxide. Some deposition of silicon oxide films involves atomic layer deposition (ALD) and/or chemical vapor deposition (CVD), but in some cases it may be difficult to achieve high quality films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods and apparatus for depositing high quality silicon oxide on a semiconductor substrate using thermal vapor-based deposition techniques. In one aspect of the disclosed embodiments, a method for depositing silicon oxide on a substrate using thermal atomic layer deposition or thermal chemical vapor deposition is provided, the method including: (a) receiving the substrate in a reaction chamber; (b) introducing a first flow of a first reactant into the reaction chamber and exposing the substrate to the first reactant, where the first reactant includes a silicon-containing reactant; (c) introducing a second flow of a second reactant into the reaction chamber to cause a reaction between the first reactant and the second reactant, (i) where the second reactant includes hydrogen (H₂) and an oxygen-containing reactant, (ii) where the reaction deposits silicon oxide on the substrate, and (iii) where the reaction is initiated when a pressure in the reaction chamber is greater than 10 Torr and equal to or less than about 40 Torr.

In some cases, (b) and (c) may occur at different times, and the silicon oxide may be deposited through thermal atomic layer deposition. In other cases, (b) and (c) may occur simultaneously, and the silicon oxide may be deposited through thermal chemical vapor deposition.

In some embodiments, the reaction is initiated when the pressure in the reaction chamber is greater than 10 Torr and equal to or less than about 20 Torr. In some embodiments, the reaction is initiated when the pressure in the reaction chamber is greater than 10 Torr and equal to or less than about 30 Torr. In various implementations, the hydrogen and oxygen-containing reactant may flow into the reaction chamber simultaneously.

In certain embodiments, a high-pressure limit switch may be in fluidic communication with the reaction chamber, and the high-pressure limit switch may be configured to trip at a maximum pressure. In some embodiments, the maximum pressure is equal to or less than about 40 Torr. In some embodiments, the maximum pressure is equal to or less than about 30 Torr. In some embodiments, the maximum pressure is equal to or less than about 20 Torr.

In various embodiments, after the reaction is initiated, the pressure in the reaction chamber may increase to at least the maximum pressure, thereby causing the high-pressure limit switch to trip, the method further including (d) stopping or reducing the second flow of the second reactant as a result of tripping the high-pressure limit switch.

In some embodiments, the oxygen-containing reactant may include a reactant selected from the group consisting of: oxygen (O₂), ozone (O₃), hydrogen peroxide (H₂O₂), water (H₂O), and combinations thereof. In some such embodiments, the oxygen-containing reactant includes oxygen (O₂).

In another aspect of the disclosed embodiments, an apparatus for depositing silicon oxide on a substrate using thermal atomic layer deposition or thermal chemical vapor deposition is provided, the apparatus including: (a) a reaction chamber; (b) an inlet for introducing reactants to the reaction chamber; (c) an outlet for removing materials from the reaction chamber; (d) a substrate support for supporting the substrate during deposition; (e) a high-pressure limit switch in fluidic communication with the reaction chamber, where the high-pressure limit switch is configured to trip if a pressure in the reaction chamber exceeds a maximum pressure, the maximum pressure being at least 10 Torr and equal to or less than about 40 Torr; and (f) a controller having at least one processor and a memory, where the at least one processor and the memory are communicatively connected with one another, and the memory stores computer-executable instructions for controlling the at least one processor to cause any of the methods described herein.

In another aspect of the disclosed embodiments, an apparatus for depositing silicon oxide on a substrate using thermal atomic layer deposition or thermal chemical vapor deposition is provided, the apparatus including: (a) a reaction chamber; (b) an inlet for introducing reactants to the reaction chamber; (c) an outlet for removing materials from the reaction chamber; (d) a substrate support for supporting the substrate during deposition; (e) a high-pressure limit switch in fluidic communication with the reaction chamber, where the high-pressure limit switch is configured to trip if a pressure in the reaction chamber exceeds a maximum pressure, the maximum pressure being at least 10 Torr and equal to or less than about 40 Torr; and (f) a controller having at least one processor and a memory, where the at least one processor and the memory are communicatively connected with one another, and the memory stores computer-executable instructions for controlling the at least one processor to cause: (i) receiving the substrate in the reaction chamber; (ii) introducing a first flow of a first reactant into the reaction chamber and exposing the substrate to the first reactant, where the first reactant includes a silicon-containing reactant; (iii) introducing a second flow of a second reactant into the reaction chamber to cause a reaction between the first reactant and the second reactant, (1) where the second reactant includes hydrogen (H₂) and an oxygen-containing reactant, (2) where the reaction deposits silicon oxide on the substrate, and (3) where the reaction is initiated when a pressure in the reaction chamber is greater than 10 Torr and equal to or less than about 40 Torr.

In some embodiments, the maximum pressure of the high-pressure limit switch may be equal to or less than about 30 Torr. In some such embodiments, the maximum pressure of the high-pressure limit switch may be equal to or less than about 20 Torr.

In some embodiments, the apparatus may be configured to flow the second reactant such that the hydrogen and oxygen-containing reactant are introduced to the reaction chamber simultaneously. In some embodiments, the controller may be configured to cause stopping or reducing the second flow of the second reactant as a result of tripping the high-pressure limit switch.

These and other aspects are described further below with reference to the drawings.

### BRIEF DESCRIPTION OF THE DRAWINGS

FIG. 1 is a flowchart describing a method of depositing silicon oxide using a thermal atomic layer deposition mechanism according to certain embodiments.

FIG. 2 is a flowchart describing a method of depositing silicon oxide using a thermal chemical vapor deposition mechanism according to certain embodiments.

FIG. 3 depicts a reaction chamber that includes an inlet above a showerhead for introducing non-reactive gas to the reaction chamber according to certain embodiments.

FIG. 4 shows a reaction chamber that may be used for depositing silicon oxide according to certain embodiments.

FIGS. 5A and 5B depict multi-station processing tools that may be used to simultaneously process several substrates according to certain embodiments.

FIGS. 6 and 7 show experimental results examining the effect of pressure on wet etch rate ratio.

FIG. 8 shows experimental results examining the effect of pressure on cycle time.

FIG. 9 shows experimental results examining the effect of different pressures and different types of deposition processes on wet etch rates at different feature depths.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Various embodiments herein relate to methods and apparatus for depositing silicon oxide. The silicon oxide may be deposited in recessed features on a surface of a semiconductor substrate. The silicon oxide may be deposited through atomic layer deposition (ALD) or chemical vapor deposition (CVD). In many cases, the deposition is driven by thermal energy. In other words, the deposition occurs through thermal ALD or thermal CVD. Thermal ALD and thermal CVD techniques are particularly useful for filling recessed features with high quality silicon oxide for gapfill applications.

The silicon oxide ALD and CVD techniques herein involve delivery of both hydrogen (H₂) and an oxygen-containing reactant (e.g., 02 and/or a different oxygen-containing reactant as described further below) to the reaction chamber. However, delivery of both hydrogen and oxygen to a high temperature reaction chamber presents certain safety challenges. For example, when hydrogen and oxygen are mixed together at high temperatures (e.g., >500° C.), an exothermic reaction occurs. At lower temperatures, this reaction typically does not occur. When processing substrates at high temperatures, there is a risk of setting off an exothermic chain reaction, which can quickly get out of control and cause an explosion or other safety hazard. The reaction of a single hydrogen molecule with a single oxygen molecule releases energy that causes reaction of additional hydrogen/oxygen molecules in the surrounding mixture, and this reaction can quickly propagate through the entire reaction chamber, potentially causing an explosion. In cases where the reaction is performed in a closed system (e.g., an adiabatic system), the hydrogen/oxygen reaction increases the pressure within the reaction chamber. Generally, if the pressure within the reaction chamber reaches greater than about 1 atmosphere (e.g., greater than about 760 Torr), there is a risk of explosion, which is a serious safety concern.

This type of safety concern can be addressed by including a high-pressure limit switch in fluidic communication with the reaction chamber. When the pressure within the reaction chamber exceeds the limit of the high-pressure limit switch, the high-pressure limit switch trips and sends a signal to a controller, which then acts to limit or stop the flow of reactants into the reaction chamber. The high-pressure limit switch typically includes a strain gauge that is calibrated to trip at a particular pressure. The pressure at which the high-pressure limit switch trips is based on the design of the strain gauge, and this pressure is not adjustable for an individual high-pressure limit switch. Many ALD and CVD reactors include a high-pressure limit switch configured to trip at 10 Torr. Because many ALD and CVD techniques are performed at very low pressures (e.g., typically less than 10 Torr), the 10 Torr high-pressure limit switch was not seen as problematic or overly limiting. Rather, it was seen as an important safety measure.

However, the inventors have discovered that silicon oxide can be safely deposited at higher pressures, and that such higher pressure depositions unexpectedly result in improved film characteristics. Specifically, deposition at about 10-40 Torr has been shown to produce silicon oxide with a relatively low, relatively uniform wet etch rate (as compared to silicon oxide deposited at <10 Torr). Further, deposition at higher pressure allows for increased throughput. Typically, techniques that produce lower wet etch rate also have the effect of decreasing throughput. It was unexpected to find a technique that both lowered the wet etch rate of the film and provided for increased throughput.

The 10 Torr high-pressure limit switch made it physically impossible to achieve the desired chamber pressure. As such, in order to operate at the desired pressures, a different high-pressure limit switch that allows a relatively higher pressure in the reaction chamber (as compared to the previous 10 Torr high-pressure limit switch) is used. In various embodiments, the high-pressure limit switch may limit the reaction chamber a maximum pressure of about 20 Torr, about 30 Torr, or about 40 Torr. Initiating/igniting the reaction at a chamber pressure of about 40 Torr or less ensures that any increase in pressure that results from an exothermic reaction between hydrogen and oxygen in the reaction chamber is limited to producing a maximum chamber pressure that does not exceed the 1 atmosphere/760 Torr limit. In other words, the reaction can be safely initiated at pressures of about 40 Torr or less, without the risk of explosion.

In various cases, at the time the reaction is initiated, the pressure in the reaction chamber may be at least about 10 Torr, at least about 12 Torr, at least about 15 Torr, at least about 20 Torr, at least about 25 Torr, or at least about 30 Torr. The upper limit on the chamber pressure at the time of initiating the reaction depends on the particular high-pressure limit switch that is used.

As mentioned above, the silicon oxide may be deposited through ALD or CVD. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form at least a partial layer of film. As an example, a silicon oxide deposition cycle may include the following operations: (i) delivery/adsorption of a silicon-containing reactant, (ii) optional purging of the silicon-containing reactant from the chamber, (iii) delivery of an oxygen-containing reactant with an optional application of energy (e.g., thermal energy or plasma energy) to drive a reaction between the adsorbed silicon-containing reactant and the oxygen-containing reactant, and (iv) optional purging of the oxygen-containing reactant (and/or plasma, if present) from the chamber. When thermal energy is used to drive the reaction between the silicon- and oxygen-containing reactants, the ALD technique is referred to as thermal ALD. By contrast, when a plasma is used to drive the reaction, the ALD technique is referred to as plasma-enhanced atomic layer deposition (PEALD). In various embodiments herein, thermal ALD is used.

During the ALD reaction, delivery or adsorption of the silicon-containing reactant may be referred to as a “dose” operation and delivery of the second reactant (e.g., hydrogen and oxygen-containing reactant) to react with the adsorbed silicon-containing reactant may be referred to as a “conversion” operation. ALD processes use surface-mediated deposition reactions to deposit films on a layer-by-layer basis.

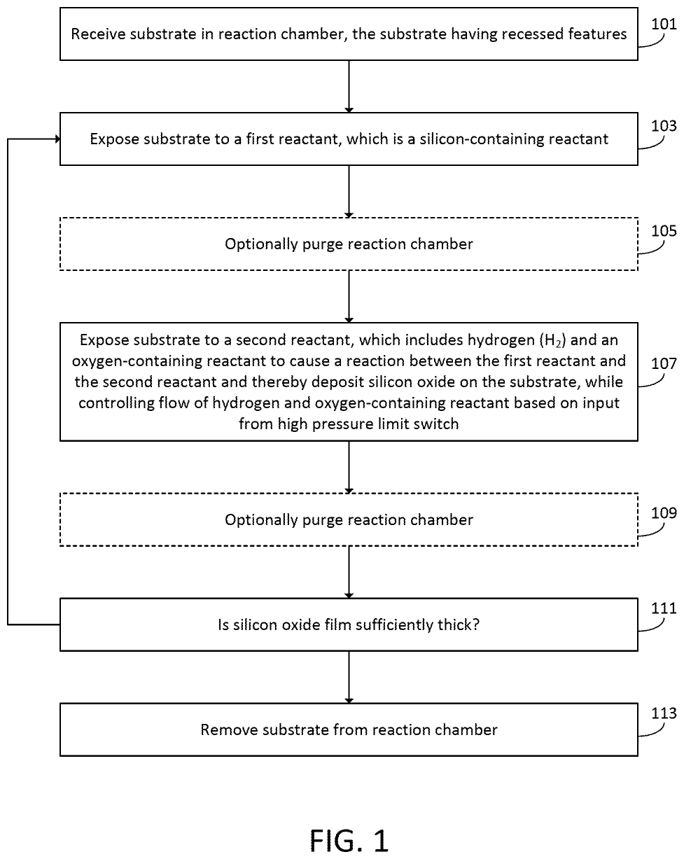

One example of a thermal ALD process for forming silicon oxide is shown in FIG. 1. In operation 101, a substrate having recessed features formed thereon is received in a reaction chamber. The recessed features are formed in a surface that includes a population of surface-active sites. In operation 103, the substrate is exposed to a first reactant, which is a silicon-containing reactant. Example flow rates for the first reactant may be between about 200-500 sccm, and example dose times for the first reactant may be between about 0.2-2 seconds. In some cases, a push gas may be provided at a flow between about 1000-2000 sccm, for example about 1500 sccm. The push gas may be flowed in an ampoule containing the silicon-containing reactant in a flow over volume setting. Molecules of the silicon-containing reactant are adsorbed onto the substrate surface, including chemisorbed species and/or physisorbed molecules of the silicon-containing reactant. It should be understood that when the compound is adsorbed onto the substrate surface as described herein, the adsorbed layer may include the compound as well as derivatives of the compound. For example, an adsorbed layer of a silicon-containing reactant may include the silicon-containing reactant as well as derivatives of the silicon-containing reactant.

After a first reactant dose of the silicon-containing reactant, the chamber is optionally evacuated and/or purged in operation 105 to remove most or all of the silicon-containing reactant remaining in gas phase so that mostly or only the adsorbed species remain. In some implementations, the chamber may not be fully evacuated. For example, the chamber may be evacuated such that the partial pressure of the silicon-containing reactant in gas phase is sufficiently low to mitigate a reaction. In some cases, a non-reactive purge gas is used such as a noble gas and/or N₂. In various embodiments, the purge/evacuation in operation 105 may have a duration of about 2 seconds or less. Where a purge gas is used, it may flow at a rate between about 25,000-65,000 sccm.

Next, at operation 107, the substrate is exposed to a second reactant including both hydrogen (Hz) and an oxygen-containing reactant, and some of these molecules react with the silicon-containing reactant adsorbed on the surface to form silicon oxide. Example flow rates for the hydrogen may be between about 2000-5000 sccm, and example flow rates for the oxygen-containing reactant may be between about 2000-20,000 sccm. Example conversion times (e.g., the duration over which the second reactant is delivered) may be between about 0.1-2 seconds.

In some processes, the second reactant reacts immediately with the adsorbed silicon-containing reactant (e.g., there is sufficient thermal energy to cause an instantaneous reaction). In other embodiments, the second reactant reacts only after a source of activation is applied temporally. In some embodiments, this source of activation is additional thermal energy provided to the substrate. In either case, the substrate may be exposed to elevated temperatures, for example between about 500-750° C. to drive the reaction. In some cases this may refer to a temperature of a substrate holder that supports the substrate during deposition.

If and when a pressure within the reaction chamber exceeds a limit of a high-pressure limit switch during deposition, the high-pressure limit switch trips and sends a signal to a controller to cause the controller to stop or restrict the flow of reactants into the reaction chamber. In various embodiments, the high-pressure limit switch may trip at a pressure greater than 10 Torr and equal to or less than about 40 Torr, in some cases equal to or less than about 30 Torr, or equal to or less than about 20 Torr.

At operation 109, the chamber may be optionally purged and/or evacuated again to remove unbound molecules of the second reactant. In some embodiments, the chamber may not be completely evacuated. The purge/evacuation in operation 109 may have a duration of about 0-1 seconds. Where a purge gas is used, it may be a non-reactive gas such as a noble gas and/or N₂, which may flow at a rate between about 25,000-65,000 sccm.

Next, at operation 111 it is determined whether the silicon oxide film is sufficiently thick. In many cases, this determination may be made based on the number of ALD cycles that have been performed, as well as the amount of silicon oxide deposited in each cycle (which is fairly uniform for a particular process). If the silicon oxide film has reached a desired thickness, the method continues with operation 113, where the substrate is removed from the reaction chamber. Otherwise, if additional film thickness is desired, the method can be repeated, starting at operation 103. The ALD steps are cycled as shown in FIG. 1 until the film reaches its final desired thickness.

In certain embodiments, an ALD first reactant dose partially saturates the substrate surface. In some embodiments, the dose phase of an ALD cycle concludes before the reactant contacts the substrate to evenly saturate the surface. Typically, the reactant flow is turned off or diverted at this point, and only purge gas flows. By operating in this sub-saturation regime, the ALD process reduces the cycle time and increases throughput. However, because reactant adsorption is not saturation limited, the adsorbed reactant concentration may vary slightly across the substrate surface.

In contrast to the ALD surface-mediated reactions, CVD relies on gas phase reactions. In CVD, reactants are delivered to the reaction chamber simultaneously and react in the gas phase. The products of the reaction are deposited on the surface of the substrate. Where thermal CVD is used, the reaction is driven by thermal energy. Where plasma enhanced CVD is used, the reaction is driven by plasma energy. In various embodiments herein, silicon oxide may be deposited using thermal CVD.

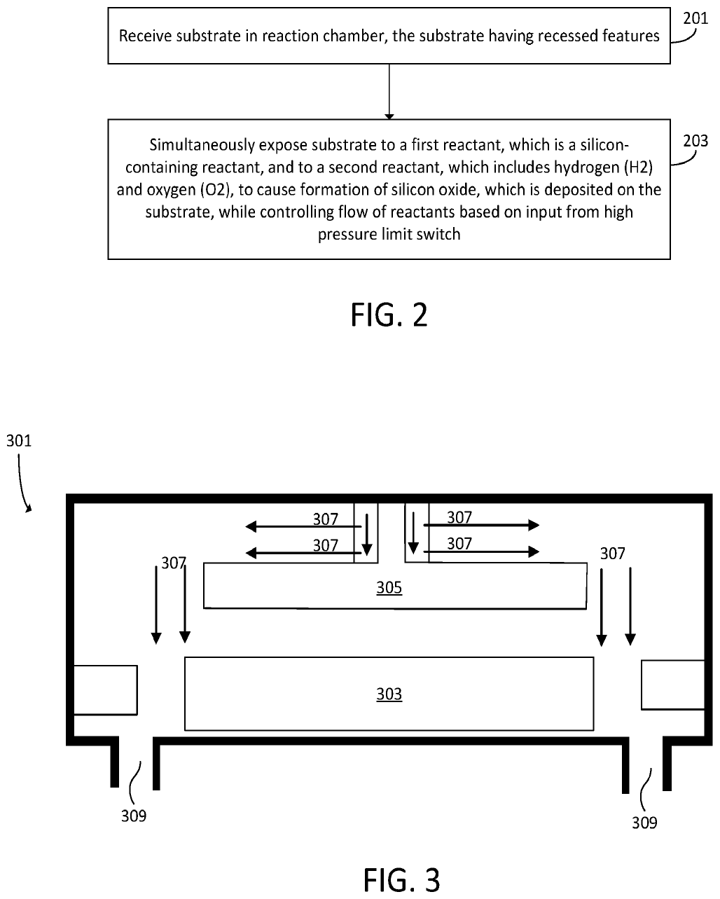

FIG. 2 illustrates a flowchart for a method of depositing silicon oxide using thermal CVD. The method begins at operation 201, where a substrate having recessed features is provided in a reaction chamber. At operation 203, a first reactant and a second reactant are simultaneously provided to the reaction chamber and react with one another in the gas phase to produce silicon oxide, which is then deposited on the surface of the substrate. The first reactant is a silicon-containing reactant, and the second reactant includes both hydrogen (H₂) and an oxygen-containing reactant. Example flow rates for the silicon-containing reactant may be between about 200-500 sccm, example flow rates for the hydrogen may be between about 2000-5000 sccm, and example flow rates for the oxygen-containing reactant may be between about 2000-20,000 sccm. As described above, a push gas may be flowed at a rate of about 1000-2000 sccm, for example about 1500 sccm. The push gas may be flowed in an ampoule containing the silicon-containing reactant in a flow over volume setting. Operation 203 occurs for a duration sufficient to form the silicon oxide film at a desired thickness. Example durations may be between about 1 second and a few hundreds of seconds, for example between about 1-400 seconds. The duration depends on the desired film thickness. During operation 203, the substrate is exposed to an elevated temperature, for example between about 500-750° C.

If and when a pressure within the reaction chamber exceeds a limit of a high-pressure limit switch during deposition, the high-pressure limit switch trips and sends a signal to a controller to cause the controller to stop or restrict the flow of reactants into the reaction chamber. Example limits for the high-pressure limit switch are discussed above.

As mentioned above, in many embodiments herein, thermal energy (not plasma energy) is used to drive the reaction between the silicon-containing reactant and the oxygen-containing reactant. In certain cases, however, the substrate may also be exposed to intermittent plasma treatments, for example between ALD cycles or between different portions of a CVD process (e.g., between depositing the first and second halves of a CVD film). It is understood that such plasma treatments, if used, modify an existing layer of material, rather than driving the reaction between the silicon- and oxygen-containing reactants to deposit new material. As such, it is understood that the deposition is still occurring through thermal ALD or thermal CVD techniques, despite exposure of the substrate to the intermittent plasma treatments.

A number of different silicon-containing reactants may be used. In some implementations, the silicon-containing reactant includes a silane, such as an aminosilane. An aminosilane includes at least one nitrogen atom bonded to a silicon atom, but may also contain hydrogens, oxygens, halogens and carbons. Examples of aminosilanes may include bis(tert-butylamino)silane (BTBAS), N-(diethylaminosilyl)-N-ethylethanamine (SAM-24), tris(dimethylamino)silane (3DMAS), and tetrakis(dimethylamino)silane (4DMAS), and trisilylamine (TSA).

Similarly, a number of different oxygen-containing reactants may be used. In some implementations, the oxygen-containing reactant may include at least one reactant selected from oxygen (O₂), ozone (O₃), hydrogen peroxide (H₂O₂), water (H₂O), and combinations thereof.

In addition to the high-pressure limit switch, one or more supplementary safety measures may be taken to reduce the risk of explosion. For instance, in some embodiments, a flow of non-reactive gas (e.g., a noble gas or N₂) may be provided within the reaction chamber. This flow of non-reactive gas can be configured to confine the reactive gases within the substrate processing space, e.g., between the showerhead and the substrate.

FIG. 3 illustrates a reaction chamber 301 configured for deposition. The reaction chamber 301 includes substrate support 303 for supporting the substrate (not shown) during deposition, and showerhead 305. The showerhead 305 acts as an inlet to deliver reactants (and other species, if relevant) to the reaction chamber 301. The flow through showerhead 305 is controlled by a controller (not shown) that is in communication with a high-pressure limit switch (not shown), which is in fluidic communication with the reaction chamber. If and when the pressure within the reaction chamber exceeds the maximum pressure of the high-pressure limit switch, the high-pressure limit switch trips and sends a signal to the controller. In response, the controller stops or limits the flow of reactants (e.g., H₂ and the oxygen-containing reactant) into the reaction chamber.

Outlets 309 are provided to remove materials from the reaction chamber 301. The outlets 309 may be connected to a vacuum source, for example. A first purge gas may be provided by the showerhead 305 during processing, for example to purge excess reactants from the reaction chamber 301 during an ALD cycle. In addition, a second purge gas (e.g., the non-reactive gas referred to above) may be provided. The flow of the second purge gas is shown by arrows 307. The second purge gas may be provided by showerhead 305 (e.g., showerhead 305 may be modified to include delivery of the reactants below the showerhead 305 and delivery of the second purge gas above the showerhead 305), or by a secondary showerhead or other gas inlet. Generally, the second purge gas is provided to fluidically confine the reactants (particularly the hydrogen and oxygen-containing reactant of the second reactant) to the region between the showerhead 305 and the substrate support 303, and break the chain reaction between the hydrogen and oxygen-containing reactant, thus stopping or dampening the energy propagation that can lead to an explosion.

### Apparatus

In various embodiments herein, thermal ALD or thermal CVD techniques are used to deposit silicon oxide. However, it is understood that such techniques may take place in a reaction chamber used for thermal processing and/or plasma processing. As such, though the following descriptions may mention the use of plasma, it is understood that such plasma features may be omitted in certain embodiments. In other embodiments, the thermal deposition techniques described herein may occur in a reaction chamber that is also used for plasma processing.

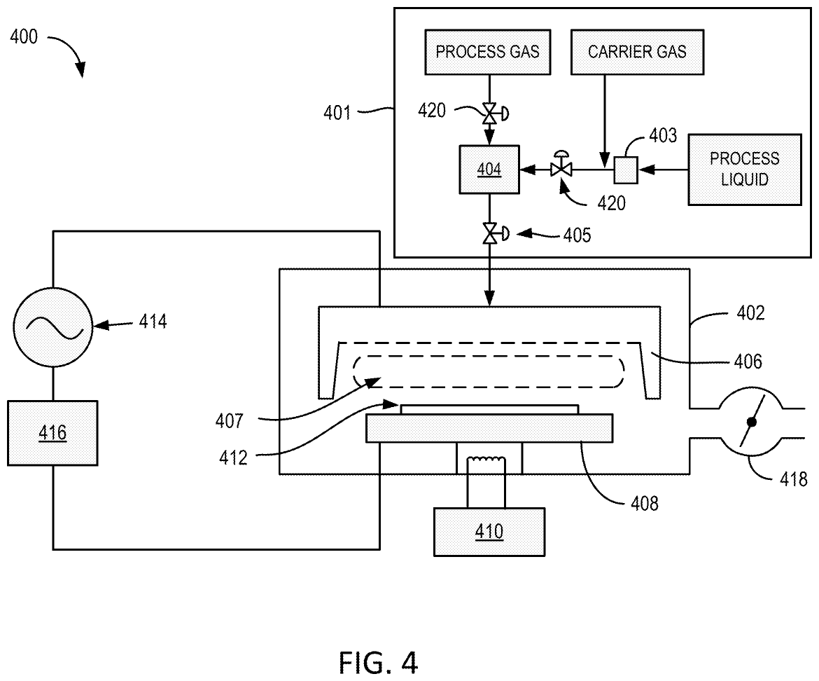

FIG. 4 schematically shows an embodiment of a process station 400 that may be used to deposit material (e.g., silicon oxide) using atomic layer deposition and/or chemical vapor deposition. For simplicity, the process station 400 is depicted as a standalone process station having a process chamber body 402 for maintaining a low-pressure environment. However, it will be appreciated that a plurality of process stations 400 may be included in a common process tool environment. Further, it will be appreciated that, in some embodiments, one or more hardware parameters of process station 400, including those discussed in detail below, may be adjusted programmatically by one or more computer controllers.

Process station 400 fluidly communicates with reactant delivery system 401 for delivering process gases to a distribution showerhead 406. Reactant delivery system 401 includes a mixing vessel 404 for blending and/or conditioning process gases for delivery to showerhead 406. One or more mixing vessel inlet valves 420 may control introduction of process gases to mixing vessel 404. Similarly, a showerhead inlet valve 405 may control introduction of process gasses to the showerhead 406.

A controller (not shown) may be used to control various aspects of process station 400, as explained further below. The controller is in communication with a high-pressure limit switch (not shown). The high-pressure limit switch may be positioned in the reaction chamber or in another location that is in fluidic communication with the reaction chamber. In this way, the pressure exposed to the high-pressure limit switch is the same as the pressure in the reaction chamber. If and when the pressure in the reaction chamber exceeds the limit of the high-pressure limit switch, the high-pressure limit switch trips and sends a signal to the controller. In response, the controller stops or otherwise limits the flow of reactants into the reaction chamber, for example by wholly or partially closing showerhead inlet valve 405 and/or mixing vessel inlet valves 420. The high-pressure limit switch may be configured to allow hydrogen and oxygen-containing reactants to flow into the reaction chamber simultaneously. Previous 10 Torr high-pressure limit switches have included a software-based interlock that prevented these species from flowing simultaneously, e.g., to reduce the risk of explosion. In various embodiments herein, this interlock is omitted.

Some reactants, like BTBAS, may be stored in liquid form prior to vaporization at and subsequent delivery to the process station. For example, the embodiment of FIG. 4 includes a vaporization point 403 for vaporizing liquid reactant to be supplied to mixing vessel 404. In some embodiments, vaporization point 403 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 403 may be heat traced. In some examples, mixing vessel 404 may also be heat traced. In one non-limiting example, piping downstream of vaporization point 403 has an increasing temperature profile extending from approximately 100° C. to approximately 150° C. at mixing vessel 404.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller upstream of vaporization point 403 may be provided for controlling a mass flow of liquid for vaporization and delivery to process station 400. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 406 distributes process gases toward substrate 412. In the embodiment shown in FIG. 4, substrate 412 is located beneath showerhead 406, and is shown resting on a pedestal 408. It will be appreciated that showerhead 406 may have any suitable shape, and may have any suitable number and arrangement of ports for distributing processes gases to substrate 412.

In some embodiments, a microvolume 407 is located beneath showerhead 406. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 408 may be raised or lowered to expose substrate 412 to microvolume 407 and/or to vary a volume of microvolume 407. For example, in a substrate transfer phase, pedestal 408 may be lowered to allow substrate 412 to be loaded onto pedestal 408. During a deposition process phase, pedestal 408 may be raised to position substrate 412 within microvolume 407. In some embodiments, microvolume 407 may completely enclose substrate 412 as well as a portion of pedestal 408 to create a region of high flow impedance during a deposition process. As mentioned with regard to FIG. 3, a secondary purge gas (not shown in FIG. 4) may be provided to confine the reactive gases within the microvolume 407.

Optionally, pedestal 408 may be lowered and/or raised during portions the deposition process to modulate process pressure, reactant concentration, etc., within microvolume 407. In one scenario where process chamber body 402 remains at a base pressure during the deposition process, lowering pedestal 408 may allow microvolume 407 to be evacuated. Example ratios of microvolume to process chamber volume include, but are not limited to, volume ratios between 1:400 and 1:10. It will be appreciated that, in some embodiments, pedestal height may be adjusted programmatically by a suitable computer controller.

In another scenario, adjusting a height of pedestal 408 may allow a plasma density to be varied during plasma activation and/or treatment cycles included in the deposition process. At the conclusion of the deposition process phase, pedestal 408 may be lowered during another substrate transfer phase to allow removal of substrate 412 from pedestal 408.

While the example microvolume variations described herein refer to a height-adjustable pedestal, it will be appreciated that, in some embodiments, a position of showerhead 406 may be adjusted relative to pedestal 408 to vary a volume of microvolume 407. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers.

Returning to the embodiment shown in FIG. 4, showerhead 406 and pedestal 408 electrically communicate with RF power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 50 kHz and 400 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions or plasma treatments. In one non-limiting example, the plasma power may be intermittently pulsed to reduce ion bombardment with the substrate surface relative to continuously powered plasmas. As mentioned above, in various embodiments herein, film is deposited through thermal ALD and/or thermal CVD techniques. As such, the components described herein for generating plasma may be omitted. In other cases, the components for generating plasma may be included, but may only be used for non-depositing plasma treatments, anneals, etc.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 408 may be temperature controlled via heater 410. Further, in some embodiments, pressure control for deposition process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to process station 400.

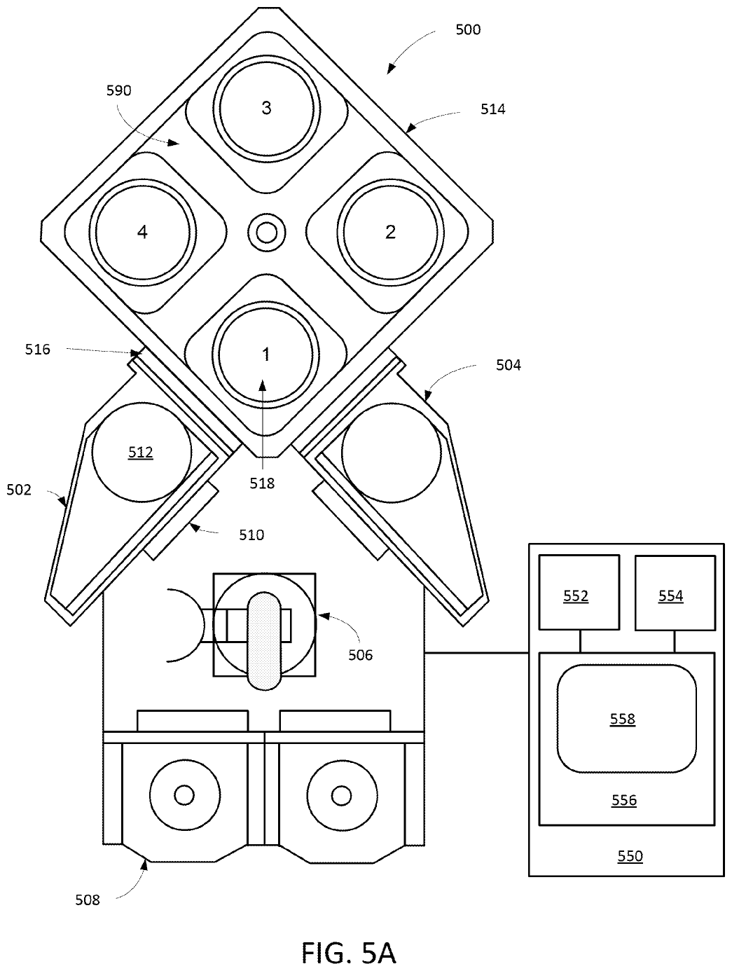

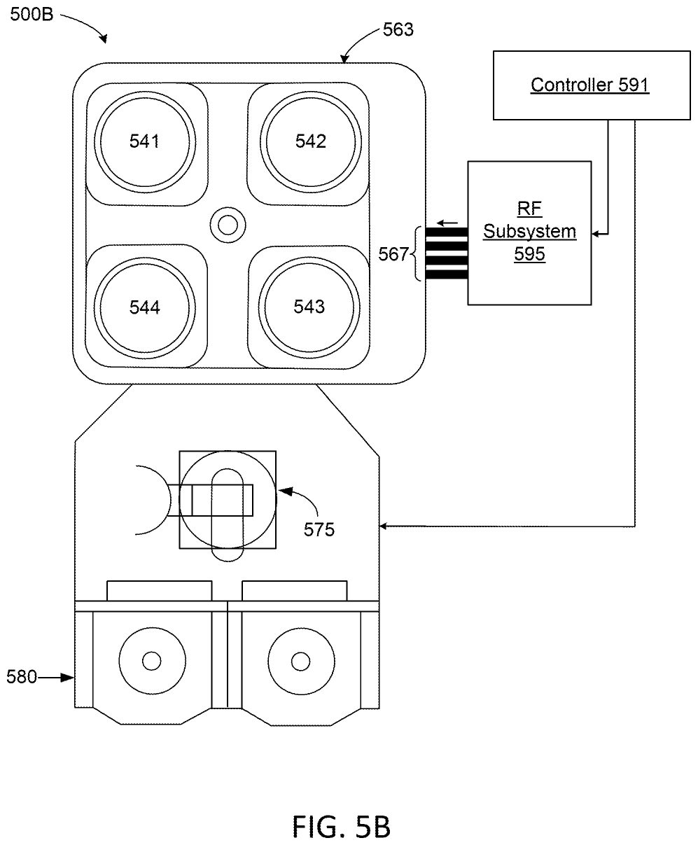

FIG. 5A shows a schematic view of an embodiment of a multi-station processing tool 500 with an inbound load lock 502 and an outbound load lock 504, either or both of which may comprise a remote plasma source. A robot 506, at atmospheric pressure, is configured to move wafers from a cassette loaded through a pod 508 into inbound load lock 502 via an atmospheric port 510. A wafer is placed by the robot 506 on a pedestal 512 in the inbound load lock 502, the atmospheric port 510 is closed, and the load lock is pumped down. Where the inbound load lock 502 comprises a remote plasma source, the wafer may be exposed to a remote plasma treatment in the load lock prior to being introduced into a processing chamber 514. Further, the wafer also may be heated in the inbound load lock 502 as well, for example, to remove moisture and adsorbed gases. Next, a chamber transport port 516 to processing chamber 514 is opened, and another robot (not shown) places the wafer into the reactor on a pedestal of a first station shown in the reactor for processing. While the embodiment depicted in FIG. 5A includes load locks, it will be appreciated that, in some embodiments, direct entry of a wafer into a process station may be provided.

The depicted processing chamber 514 comprises four process stations, numbered from 1 to 4 in the embodiment shown in FIG. 5A. Each station has a heated pedestal (shown at 518 for station 1), and gas line inlets. It will be appreciated that in some embodiments, each process station may have different or multiple purposes. While the depicted processing chamber 514 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 5A also depicts an embodiment of a wafer handling system 590 for transferring wafers within processing chamber 514. In some embodiments, wafer handling system 590 may transfer wafers between various process stations and/or between a process station and a load lock. It will be appreciated that any suitable wafer handling system may be employed. Non-limiting examples include wafer carousels and wafer handling robots. FIG. 5A also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog and/or digital input/output connections, stepper motor controller boards, etc.

In some embodiments, system controller 550 controls all of the activities of process tool 500. System controller 550 executes system control software 558 stored in mass storage device 554, loaded into memory device 556, and executed on processor 552. System control software 558 may include instructions for controlling the timing, mixture of gases, delivery of gases to the chamber and/or stations, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 500. System control software 558 may be configured in any suitable way. For example, various process tool component subroutines or control objects may be written to control operation of the process tool components necessary to carry out various process tool processes in accordance with the disclosed methods. System control software 558 may be coded in any suitable computer readable programming language.

In various embodiments, the system controller 550 is in communication with a high-pressure limit switch (not shown) that is in fluidic communication with the processing chamber 514. If and when the pressure in the processing chamber 514 exceeds a limit of the high-pressure limit switch, the high-pressure limit switch trips and sends a signal to the system controller 550. In response, the system controller 550 stops or otherwise limits the flow of reactants into the processing chamber 514.

In some embodiments, system control software 558 may include input/output control (IOC) sequencing instructions for controlling the various parameters described above. For example, each phase of a PEALD process may include one or more instructions for execution by system controller 550. The instructions for setting process conditions for a PEALD process phase may be included in a corresponding PEALD recipe phase. In some embodiments, the PEALD recipe phases may be sequentially arranged, so that all instructions for a PEALD process phase are executed concurrently with that process phase.

Other computer software and/or programs stored on mass storage device 554 and/or memory device 556 associated with system controller 550 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 518 and to control the spacing between the substrate and other parts of process tool 500.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 550 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 550 from various process tool sensors. The signals for controlling the process may be output on the analog and digital output connections of process tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

In some implementations, a system controller 550 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 550, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

FIG. 5B depicts a schematic view of another embodiment of a multi-station processing tool, similar to that shown in FIG. 5A. Processing apparatus 500B employs an integrated circuit fabrication chamber 563 that includes multiple fabrication process stations, each of which may be used to perform processing operations on a substrate held in a wafer holder, such as a pedestal, at a particular process station. In the embodiment of FIG. 5B, the integrated circuit fabrication chamber 563 is shown having four process stations 541, 542, 543, and 544. Other similar multi-station processing apparatuses may have more or fewer process stations depending on the implementation and, for example, a desired level of parallel wafer processing, size/space constraints, cost constraints, etc. Also shown in FIG. 5B is substrate handler robot 575, which may operate under the control of system controller 591, configured to move substrates from a wafer cassette (not shown in FIG. 5B) from loading port 580 and into integrated circuit fabrication chamber 563, and onto one of process stations 541, 542, 543, and 544.

FIG. 5B also depicts an embodiment of a system controller 591 employed to control process conditions and hardware states of processing apparatus 500B. System controller 591 may include one or more memory devices, one or more mass storage devices, and one or more processors. System controller 591 may be as described in relation to system controller 550 of FIG. 5A.

In certain embodiments, RF subsystem 595 may generate and convey RF power to integrated circuit fabrication chamber 563 via radio frequency input ports 567. In particular embodiments, integrated circuit fabrication chamber 563 may comprise input ports in addition to radio frequency input ports 567 (additional input ports not shown in FIG. 5B). Accordingly, integrated circuit fabrication chamber 563 may utilize 8 RF input ports. In particular embodiments, process stations 541-544 of integrated circuit fabrication chamber 165 may each utilize first and second input ports in which a first input port may convey a signal having a first frequency and in which a second input port may convey a signal having a second frequency. Use of dual frequencies may bring about enhanced plasma characteristics. In various embodiments herein, the substrate is not exposed to plasma, or is only exposed to non-depositing plasmas to anneal or otherwise treat a deposited film.

### EXPERIMENTAL

The inventors have shown that the techniques described herein may be used to safely deposit high quality silicon oxide using thermal vapor-based deposition techniques at high throughput. Notably, silicon oxide films formed at relatively higher pressure (e.g., between about 10-40 Torr) according to the disclosed techniques show a lower wet etch rate ratio than comparable films deposited at relatively lower pressure (e.g., at <10 Torr). Further, the relatively high-pressure enables shorter processing times, thus increasing throughput. Because techniques that improve/lower the wet etch rate ratio also tend to decrease throughput, it was unexpected that the change to higher processing pressure improved both of these factors.

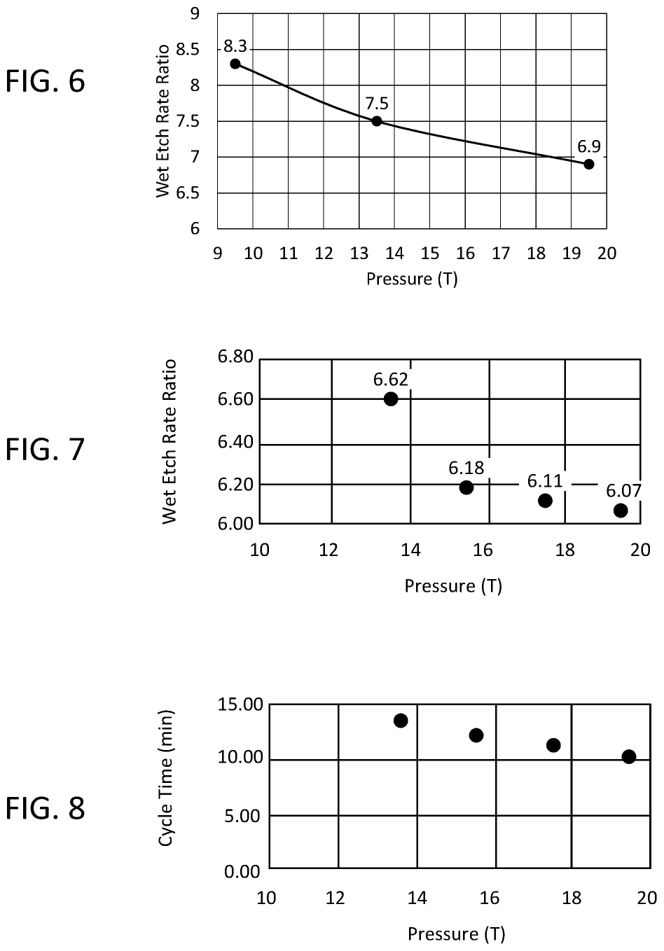

FIGS. 6-8 show experimental results examining the effect of pressure on the wet etch rate ratio (FIGS. 6 and 7) and on the cycle time (FIG. 8). The pressure refers to the pressure within the reaction chamber when the reaction is initiated. In the examples of FIGS. 6-8, a 20 Torr high-pressure limit switch was used. As such, in these examples, the reaction was always initiated at a chamber pressure of about 20 Torr or less, as shown in the figures. The wet etch rate ratio refers to the wet etch rate of the deposited material (e.g., within a recessed feature) compared to the wet etch rate of a standard silicon oxide. For example, a material that etches twice as fast as the standard silicon oxide under a particular set of conditions is understood to have a wet etch rate ratio of 2. Likewise, a material that etches four times as fast as the standard silicon oxide under a particular set of conditions is understood to have a wet etch rate ratio of 4. Lower wet etch rates and wet etch rate ratios indicate a slower etching, higher quality film. As such, in the context of silicon oxide gapfill, it is generally desirable for the wet etch rate to be relatively low, and for the wet etch rate ratio to be close to 1.

FIG. 6 presents results related to silicon oxide depositions that occurred at about 550° C. using BTBAS (e.g., bis(t-butylamino)silane). FIG. 7 presents results related to silicon oxide depositions that occurred at about 650° C. using 3DMAS (e.g., tris(dimethylamino)silane). In both cases, the reactions occurred through thermal ALD techniques. The results in FIGS. 6 and 7 show that in the range of 10-20 Torr, increased pressure leads to lower wet etch rate ratios. In other words, the increased pressure resulted in higher quality silicon oxide films.

FIG. 8 presents results showing the effect of pressure on cycle time. In the range of 10-20 Torr, increased pressure led to decreased cycle time. Because cycle time is inversely proportional to throughput, the decreased cycle time at higher pressures corresponds to higher throughput.

While the results in FIGS. 6-8 are limited to the range of about 10-20 Torr, it is believed that such trends continue at higher pressures. However, in order to ensure that the reaction can be performed safely, the pressure in the reaction chamber should not be allowed to increase beyond about 1 atmosphere/760 Torr. It is believed that if the reaction is initiated while the reaction chamber is at a pressure of about 40 Torr or less, any increase in pressure that results from a reaction between hydrogen and an oxygen-containing reactant will be sufficiently small to remain under the 1 atmosphere/760 Torr limit.

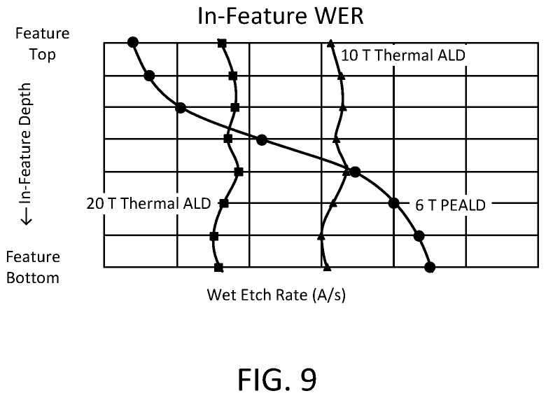

FIG. 9 presents experimental results examining the effect of different types of deposition processes on the wet etch rate (WER) at different in-feature depths. Two different thermal ALD processes were examined, one at 10 Torr and one at 20 Torr. Both thermal ALD processes resulted in relatively constant wet etch rate throughout the entire feature depth, which is desirable. The film deposited at 20 Torr exhibited a substantially lower wet etch rate compared to the film deposited at 10 Torr. These results suggest that film quality is improved with higher deposition pressures. FIG. 9 also presents results for a plasma enhanced ALD process performed at 6 Torr. In this case, the wet etch rate is non-uniform, with a lower wet etch rate near the top of the feature and a higher wet etch rate near the bottom of the feature. It is believed that this non-uniformity is a result of relatively greater ion bombardment near the top of the feature that selectively densities the film near the top of the feature. Generally, this non-uniformity is not desirable.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for depositing silicon oxide on a substrate using thermal atomic layer deposition or thermal chemical vapor deposition, the method comprising:
a. receiving the substrate in a reaction chamber;
b. introducing a first flow of a first reactant into the reaction chamber and exposing the substrate to the first reactant, wherein the first reactant comprises a silicon-containing reactant;
c. introducing a second flow of a second reactant into the reaction chamber to cause a reaction between the first reactant and the second reactant,
i. wherein the second reactant comprises hydrogen (H₂) and an oxygen-containing reactant,
ii. wherein the reaction deposits silicon oxide on the substrate, and
iii. wherein the reaction is initiated when a pressure in the reaction chamber is greater than 10 Torr and equal to or less than about 40 Torr.

2. The method of claim 1, wherein (b) and (c) occur at different times, and the silicon oxide is deposited through thermal atomic layer deposition.

3. The method of claim 1, wherein (b) and (c) occur simultaneously, and the silicon oxide is deposited through thermal chemical vapor deposition.

4. The method of claim 1, wherein the reaction is initiated when the pressure in the reaction chamber is greater than 10 Torr and equal to or less than about 20 Torr.

5. The method of claim 1, wherein the reaction is initiated when the pressure in the reaction chamber is greater than 10 Torr and equal to or less than about 30 Torr.

6. The method of claim 1, wherein the hydrogen and oxygen-containing reactant flow into the reaction chamber simultaneously.

7. The method of claim 1, wherein a high-pressure limit switch is in fluidic communication with the reaction chamber, and wherein the high-pressure limit switch is configured to trip at a maximum pressure.

8. The method of claim 7, wherein the maximum pressure is equal to or less than about 40 Torr.

9. The method of claim 7, wherein the maximum pressure is equal to or less than about 30 Torr.

10. The method of claim 7, wherein the maximum pressure is equal to or less than about 20 Torr.

11. The method of claim 7, wherein after the reaction is initiated, the pressure in the reaction chamber increases to at least the maximum pressure, thereby causing the high-pressure limit switch to trip, the method further comprising:
d. stopping or reducing the second flow of the second reactant as a result of tripping the high-pressure limit switch.

12. The method of claim 1, wherein the oxygen-containing reactant comprises a reactant selected from the group consisting of: oxygen (O₂), ozone (O₃), hydrogen peroxide (H₂O₂), water (H₂O), and combinations thereof.

13. The method of claim 12, wherein the oxygen-containing reactant comprises oxygen (O₂).

14. An apparatus for depositing silicon oxide on a substrate using thermal atomic layer deposition or thermal chemical vapor deposition, the apparatus comprising:
a. a reaction chamber;
b. an inlet configured to introduce reactants to the reaction chamber;
c. an outlet configured to remove materials from the reaction chamber;
d. a substrate support configured to support the substrate during deposition;
e. a high-pressure limit switch in fluidic communication with the reaction chamber, wherein the high-pressure limit switch is configured to trip if a pressure in the reaction chamber exceeds a maximum pressure, the maximum pressure being at least 10 Torr and equal to or less than about 40 Torr; and
f. a controller having at least one processor and a memory, wherein the at least one processor and the memory are communicatively connected with one another, and the memory stores computer-executable instructions for controlling the at least one processor to cause the method of claim 1.

15. An apparatus for depositing silicon oxide on a substrate using thermal atomic layer deposition or thermal chemical vapor deposition, the apparatus comprising:
a. a reaction chamber;
b. an inlet configured to introduce reactants to the reaction chamber;
c. an outlet configured to remove materials from the reaction chamber;
d. a substrate support configured to support the substrate during deposition;
e. a high-pressure limit switch in fluidic communication with the reaction chamber, wherein the high-pressure limit switch is configured to trip if a pressure in the reaction chamber exceeds a maximum pressure, the maximum pressure being at least 10 Torr and equal to or less than about 40 Torr; and
f. a controller having at least one processor and a memory, wherein the at least one processor and the memory are communicatively connected with one another, and the memory stores computer-executable instructions for controlling the at least one processor to cause:
i. receiving the substrate in the reaction chamber;
ii. introducing a first flow of a first reactant into the reaction chamber and exposing the substrate to the first reactant, wherein the first reactant comprises a silicon-containing reactant;
iii. introducing a second flow of a second reactant into the reaction chamber to cause a reaction between the first reactant and the second reactant,
1. wherein the second reactant comprises hydrogen (H₂) and an oxygen-containing reactant,
2. wherein the reaction deposits silicon oxide on the substrate, and
3. wherein the reaction is initiated when a pressure in the reaction chamber is greater than 10 Torr and equal to or less than about 40 Torr.

16. The apparatus of claim 15, wherein the maximum pressure of the high-pressure limit switch is equal to or less than about 30 Torr.

17. The apparatus of claim 16, wherein the maximum pressure of the high-pressure limit switch is equal to or less than about 20 Torr.

18. The apparatus of claim 15, wherein the apparatus is configured to flow the second reactant such that the hydrogen and oxygen-containing reactant are introduced to the reaction chamber simultaneously.

19. The apparatus of claim 15, wherein the controller is configured to cause stopping or reducing the second flow of the second reactant as a result of tripping the high-pressure limit switch.
